(19) United States
(12) Patent Application Publication
(10) Pub. No.: US 2004/0182701 A1
(43) Pub. Date: Sep. 23, 2004

(54) Sputtering apparatus, a mixed film produced by the sputtering apparatus and a multilayer film including the mixed film

(75) Inventor: Masao Miyamura, Fukushima (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Aashi Glass Company, Limited, TOKYO (JP)

(21) Appl. No.: 10/765,140

(22) Filed: Jan. 28, 2004

(30) Foreign Application Priority Data
Jan. 29, 2003 (JP) 2003-020193

(51) Int. Cl. C23C 14/32

(52) U.S. Cl. 204/298.26; 204/298.11; 204/298.28; 204/298.08; 204/192.12

(57) ABSTRACT

A sputtering apparatus for producing a mixed film having a stoichiometrically complete composition and a refractive index corresponding to a designed value without reducing the film deposition rate, a mixed film produced by such sputtering apparatus and a multilayer film including the mixed film are provided.

A sputtering apparatus 100 comprising a vacuum chamber 1, a cylindrical substrate holder 9 supported rotatably in the vacuum chamber and a substrate 10 mounted on an outer periphery of the substrate holder wherein the vacuum chamber 1 includes a first film deposition area A and a second film deposition area B for deposition of a film on the substrate, the first film deposition area A includes a first sputtering source 35 and a first plasma generator 51, and the second film deposition area B includes a second sputtering source 36 and a second plasma generator 52, and the first sputtering source 35 and the first plasma generator 51 are physically isolated from each other and the second sputtering source 36 and the second plasma generator 52 are physically isolated from each other.

### BACKGROUND OF THE INVENTION

1. Field of the Invention

The present invention relates to a sputtering apparatus used mainly for producing a thin dielectric film for an optical device, a mixed film produced by such sputtering apparatus and a multilayer film including the mixed film.

2. Discussion of Background

As methods for producing a multilayer film used for a thin dielectric film for an optical device, an electron beam vacuum deposition method has widely been used. Recently, use of a sputtering method has been increasing because accuracy in controlling the film thickness is high and the film can be formed in a stable manner.

As materials for a multilayer film, oxides such as SiO₂, Ta₂O₅, TiO₂ etc. have widely been employed. In the conventional sputtering method, however, there was a problem that productivity was low since the sputter yield of such oxides was low and the film deposition rate was low. Further, since an oxide target is an insulating material, it was necessary to use a high frequency sputtering method. However, the high frequency sputtering method was disadvantageous in that cost for the apparatus was high and the film deposition rate was low with the result of low productivity.

In order to increase the film deposition rate, it can be considered that a DC sputtering method is employed to increase the sputtering rate. For the formation of an oxide film, a DC reactive sputtering method may be used wherein film deposition is conducted by using a metal target or a target having an incomplete oxide (a target having oxygen deficient and a non-stoichiometric composition) and an oxygen gas. In this case, however, the surface of the target is oxidized by the oxygen gas during depositing of the film to form an insulator whereby the film deposition rate decreases remarkably or the discharging becomes unstable. Accordingly, it was necessary to keep the surface of the target constant by strictly controlling the discharge state accurately.

In order to solve the above-mentioned problems, a so-called double magnetron sputtering method or twin magnetron sputtering method wherein a discharge voltage is applied alternately to a pair of cathodes by using an AC power source to prevent an electric charge from accumulating on the target surface whereby a stabilized discharge and a high sputtering rate are obtainable, is disclosed (see, for example, JP-A-4-325680).

Further, a method for forming an oxide film by using plasma instead of the oxygen gas is disclosed (see, for example, JP-A-8-511830). However, such method as described in JP-A-8-511830 can not solve completely the problem that the surface of the target partly turns insulators by the oxide formation, as a result, during the deposition of film, the film deposition rate decreases largely. The oxide formation on the target surface and the reduction of deposition rates are mainly due to the configuration that the target portion and the plasma supply portion are not partitioned from each other and there is connection of each discharge.

Further, in optical devices in recent years, in particular, various filters or light emitting devices used for optical communication are required to have a further high performance in comparison with conventional ones. In a thin film interference filter, for example, such one formed by laminating alternately a high refractive index film and a low refractive index film is usually used. However, when only the high refractive index film and the low refractive index film are simply laminated alternately, there takes place a problem that a ripple results in the filter characteristics (e.g., wavelength dependence of the transmittance or reflectance). In order to solve such problem, there is a proposal of laminating in the multilayer film a plurality of interlayers having a refractive index of an intermediate value between the refractive index of a high refractive index film and the refractive index of a low refractive index film. By providing such interlayers, the ripple can be reduced remarkably or the total number of the layers can be reduced. However, in order to produce such interlayers, it is necessary to use as a target the third material having a refractive index different from that of the high refractive index target or the low refractive index target. The necessity of providing three different types of targets creates a problem of increasing the size of the apparatus and increasing the cost.

For solving the above-mentioned problem, if a mixed film formed by mixing the material for the high refractive index film and the material for the low refractive index film can be prepared so as to have a desired refractive index between them as an interlayer, the target for producing the interlayer is unnecessary and the cost for it can be omitted. Further, if such interlayer is added and stacked in a single or plural number, a multilayer film having a required high degree of optical performance with a less number of layers can be produced, and productivity can be improved.

As methods for producing the mixed film, there is known a so-called cosputtering method wherein two appropriate kinds of targets are subjected simultaneously to electric discharge in a limited area so that two kinds of materials are mixed to thereby form the mixed film (see, for example, “Cosputtered films of mixed TiO₂/SiO₂” by R. Laird and one other, J. Vac. Sci. Technol. 1992, A10(4), p. 1908-1912). However, when the mixed film was formed by the cosputtering method, that is, by the simultaneous electric discharge on the both targets composed of materials having different refractive indices cross-contamination took place between the both targets and reproducibility of the film composition became poor. Further, conditions for conducting the sputtering stably with high deposition rates to the both target materials might not always be provided. Accordingly, there was the problem of incapability of mass production from the viewpoint of the stability of electric discharge and yields.

Further, in order to obtain a stabilized discharge and a high film deposition rate, a cosputtering method using the double magnetron sputtering method or the twin magnetron sputtering method can be employed. Even in such cosputtering methods, a stable discharge condition and a high film deposition rate with respect to a plurality of targets composed of different materials should be realized simultaneously in the same vacuum chamber. However, such state could not always be provided, and were deviated from the optimum condition with respect to individual targets. Accordingly, it was difficult to conduct the film deposition with good reproducibility.

In addition, a method for producing a mixed film with increased film deposition rates, wherein a thin film of about 1 atomic layer of metal is first formed by a sputtering method, and the formed thin metal film is oxidized efficiently by a physically spaced oxygen gas plasma from the sputtering target to produce an oxide film (referred to as a so-called meta mode method or radical assist sputtering method), is disclosed (see, for example, JP-A-11-256327).

A sputtering apparatus using such meta mode method or the radical assist sputtering method will be explained with reference to FIG. 3. FIG. 3 is a schematic plane view showing the structure of the sputtering apparatus 300 described in JP-A-11-256327 wherein the sputtering apparatus 300 comprises a vacuum chamber 101, a cylindrical substrate holder 109 placed in the vacuum chamber and substrates 110 mounted on an outer periphery of the substrate holder 109, and each substrate 110 is supported rotatably around the center axis of substrate holder 109, as the center of revolution.

The vacuum chamber 101 includes a first sputtering source 135 comprising a first cathode 121 and a first target 131 located in front of the first cathode 121, a second sputtering source 136 comprising a second cathode 122 and a second target 132 located in front of the second cathode 122 and a plasma generator 151 located apart from both sputtering sources 135, 136. A first shutter 141 and a second shutter 142 are provided in film deposition areas with respect to the first and second sputtering sources 135, 136, the first and second shutters 141, 142 being adapted to start or stop the deposition of films. The vacuum chamber 101 further includes partition plates (shielding plates) 171, 172 to isolate each sputtering source from plasma generator.

When the mixed film is formed by sputtering in the sputtering apparatus 300 shown in FIG. 3, a mixed film of mixed metals should be formed on a substrate by using the first and second sputtering sources 135, 136, and then, oxidized by reacting the mixed film of mixed metals with a reactive gas, e.g., an oxygen radical produced by the plasma generator 51.

However, the degree of oxidation of metals depends largely on the reactivity of each metal. When an oxidized mixed film is produced by oxidizing two kinds of metals having fairly different reactivity with respect to a reactive gas, there is a large limitation in choosing materials. Namely, a high reactive metal can sufficiently be oxidized to form an oxide satisfying completely the stoichiometric ratio. On the other hand, a low reactive metal can not sufficiently be oxidized and remains in a partly reduction state. Accordingly, it was difficult to form a completely oxidized mixed film in which each metal comprises the stoichiometrically complete composition at the same time. Accordingly, there was such problem that the formed oxidized mixed film became an absorptive film having a higher extinction coefficient, the refractive index estimated from a mixture ratio was deviated largely from the designed value, or the film deposition rate for oxidizing completely the both metals was decreased.

Further, an oxide multilayer film producing apparatus is disclosed wherein substrates are mounted around a drum type rotary cylinder and two targets and one oxidizing plasma source are activated while the drum is rotated, whereby an oxidized multilayer film is formed (see, for example, JP-A-3-229870). However, this method had the same problem as in JP-A-11-256327 in the viewpoint that there was a difference in the reactivity between both target materials although this method employed mainly ions for the oxidation reaction in comparison with the method described in JP-A-11-256327.

It is an object of the present invention to provide a sputtering apparatus for producing a mixed film having a stoichiometrically complete composition and a refractive index agreeable with a designed value without reducing the film deposition rate, a mixed film produced by such sputtering apparatus, and a multilayer film including the mixed film and having the optical property agreeable with a designed value, e.g., a sufficient reflection or transmission performance.

### SUMMARY OF THE INVENTION

In accordance with the present invention, there is provided a sputtering apparatus comprising a vacuum chamber, a cylindrical substrate holder supported rotatably in the vacuum chamber and a substrate mounted on an outer periphery of the substrate holder wherein the vacuum chamber includes a first film deposition area and a second film deposition area for deposition of a film on the substrate, the first film deposition area includes a first sputtering source comprising a first cathode and a first target held on the first cathode and a first plasma generator located so as to be adjacent to the first sputtering source, and the second film deposition area includes a second sputtering source comprising a second cathode and a second target held on the second cathode and a second plasma generator located so as to be adjacent to the second sputtering source, and the first sputtering source and the first plasma generator are partitioned from each other and the second sputtering source and the second plasma generator are partitioned from each other.

Further, in accordance with the present invention, there is provided a sputtering apparatus comprising a vacuum chamber, a circular disk-like substrate holder supported rotatably in the vacuum chamber and a substrate mounted on the circular disk of the substrate holder wherein the vacuum chamber includes a first film deposition area and a second film deposition area for deposition of a film on the substrate, the first film deposition area includes a first sputtering source comprising a first cathode and a first target held on the first cathode and a first plasma generator located so as to be adjacent to the first sputtering source, and the second film deposition area includes a second sputtering source comprising a second cathode and a second target held on the second cathode, and a second plasma generator located so as to be adjacent to the second sputtering source, and the first sputtering source and the first plasma generator are partitioned from each other and the second sputtering source and the second plasma generator are partitioned from each other.

Further, in accordance with the present invention, there is provided a mixed film formed on a substrate by using either of the above-mentioned sputtering apparatuses and by repeating the following operations: depositing on the substrate a film of an electrically conductive material, as the material for the first target, by sputtering at the first sputtering source, causing a reaction of the formed film by the first plasma generator, depositing a film of an electrically conductive material, as the material for the second target, by sputtering at the second sputtering source, and causing a reaction of the formed film by the second plasma generator.

Further, in accordance with the present invention, there is provided a multilayer film including the above-mentioned mixed film.

### BRIEF DESCRIPTION OF THE DRAWINGS

FIG. 1 is a schematic plane view showing the structure of the sputtering apparatus according to an embodiment of the present invention;

FIG. 2 is a schematic plane view showing the structure of the sputtering apparatus according to another embodiment of the present invention;

FIG. 3 is a schematic plane view showing the structure of a conventional sputtering apparatus;

FIG. 4 is a schematic plane view showing the structure of the sputtering apparatus according to another embodiment of the present invention, and FIG. 5 is a schematic plane view showing the structure of the sputtering apparatus according to another embodiment of the present invention.

### DETAILED DESCRIPTION OF THE PREFERRED EMBODIMENTS

In the following, preferred embodiments of the sputtering apparatus, the mixed film produced by the sputtering apparatus and the multilayer film including the mixed film according to the present invention will be described with reference to the drawing.

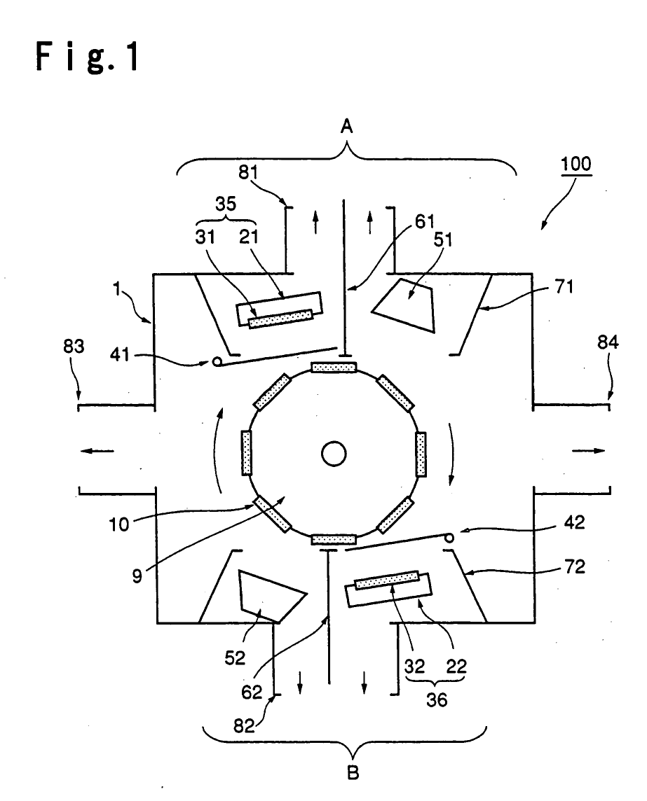

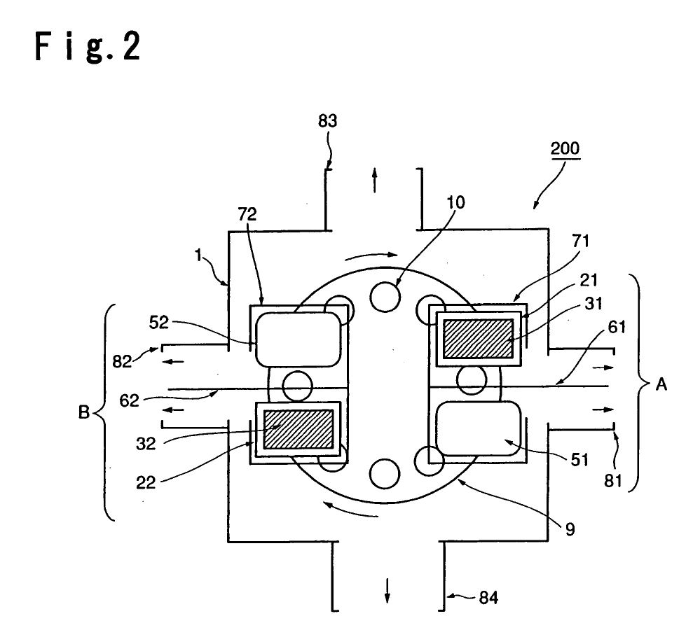

FIG. 1 is a schematic plane view showing the structure of the sputtering apparatus according to an embodiment of the present invention, and FIG. 2 is a schematic plane view showing the structure of the sputtering apparatus according to another embodiment of the present invention.

In FIG. 1, a sputtering apparatus 100 comprises a vacuum chamber 1, a cylindrical substrate holder 9 placed in the vacuum chamber and substrates 10 mounted on an outer periphery of the substrate holder 9 wherein the substrates 10 are supported rotatably around the center axis, as the center of revolution, of the substrate holder 9.

The vacuum chamber 1 as a reaction chamber, is connected to an exhaust pump (not shown) to obtain a low pressure necessary for sputtering by evacuating air in the vacuum chamber 1. The vacuum chamber 1 is provided with a gas supply means (not shown) for supplying sputtering gas and reaction gas, and a loading door.

As shown in FIG. 1, the substrate holder 9 is rotated in the direction indicated by arrow marks at a constant speed (at, for example, 100 rpm) by means of a rotating unit (not shown). Inside the vacuum chamber 1, a first film deposition area A and a second film deposition area B are provided so that different kinds of films can be deposited on the substrates 10 by rotating the substrate holder 9. For example, a low refractive index film can be deposited in the first film deposition area A and,a high refractive index film can be deposited in the second film deposition area B.

In the first film deposition area A, a first sputtering source 35 comprising a first cathode 21 and a first target 31 held on the first cathode 21 and a first plasma generator 51 located so as to be adjacent to the first sputtering source 35 and driven by microwave power are provided. The first cathode 21 may be a so-called double magnetron cathode for supplying alternately to a pair of cathodes a discharge voltage from an AC power source or a DC pulse power source to avoid accumulation of electric charge onto a target to thereby stabilize the discharge and increase the speed of sputtering. As the microwave discharge for generating plasma from the generator, an ECR discharge as a microwave discharge having a high discharge density may be used, or an inductive or capacitive coupling type high frequency discharge may be used instead of the microwave discharge.

During the revolution of the substrate holder 9 in the first film deposition area A, a material of the first target 31 is deposited on a substrate by means of a first sputtering source 35, and then, the deposited film reacts by means of the first plasma generator 51 located adjacent to the first sputtering source 35 whereby a dielectric film is formed on the substrate.

Although the first sputtering source 35 and the first plasma generator 51 are adjacent to each other, they should be spaced (separated) physically from each other (they should be partitioned from each other). “Adjacent” does not mean a completely adjacent state but means that any device affecting the film deposition is not provided therebetween. “Physically spaced” means that the reactive gas generated from the first plasma generator 51 does not diffuse to such an extent that it affects the discharge of the first target 31, and they are located apart from each other so that the film deposition by the sputtering can be carried out in a stable manner. For this purpose, it is preferable to provide a separation means such as a partition plate 61, an atmosphere separating cover 71, an exhaust port 81 or the like, which will be described later.

The partition plate 61 is provided between the first sputtering source 35 and the first plasma generator 51 so that the surface of the first target 31 is prevented from being polluted to become an insulator by the reactive gas decomposed and migrated from the first plasma generator 51. Further, the atmosphere separating cover 71 is provided to define the first plasma generator 51 in the vacuum chamber 1 so that the vacuum portion in the vacuum chamber 1 is prevented from being polluted by the reactive gas decomposed and migrated from the first plasma generator 51. Further, the exhaust port 81 is provided in rear of the first plasma generator 51 so that the reactive gas decomposed and migrated from the first plasma generator 51 can effectively be evacuated to prevent the inside of the vacuum chamber 1 from being polluted. The partition plate 61 and the atmosphere separating cover 71 serve to control unstableness of the discharge due to electrical interference between the sputter discharge and the plasma discharge.

In FIG. 1, the second film deposition area B is provided at a position apart from the first film deposition area A in the vacuum chamber 1. In the second film deposition area B in the same manner as the first film deposition area A, a second sputtering source 36 comprising a second cathode 22 and a second target 32, a second shutter 42, a second plasma generator 52, a partition plate 62, an atmosphere separating cover 72 and an exhaust port 82 are provided. Further, in the same manner as the first sputtering source 35, the second sputtering source 36 and the second plasma generator 52 should be partitioned from each other.

FIG. 1 shows an embodiment that a plurality of substrates 10 are mounted on the outer periphery of the cylindrical substrate holder 9. When a large-sized substrate having a diameter or a length of one side of 6 inches (152.4 mm) is used, it is preferable to use a circular disk-like substrate holder 9 as shown in FIG. 2 and to mount the substrates 10 on the circular disk of the substrate holder 9 from the viewpoint of stabilizing the film thickness and the quality of the deposited film.

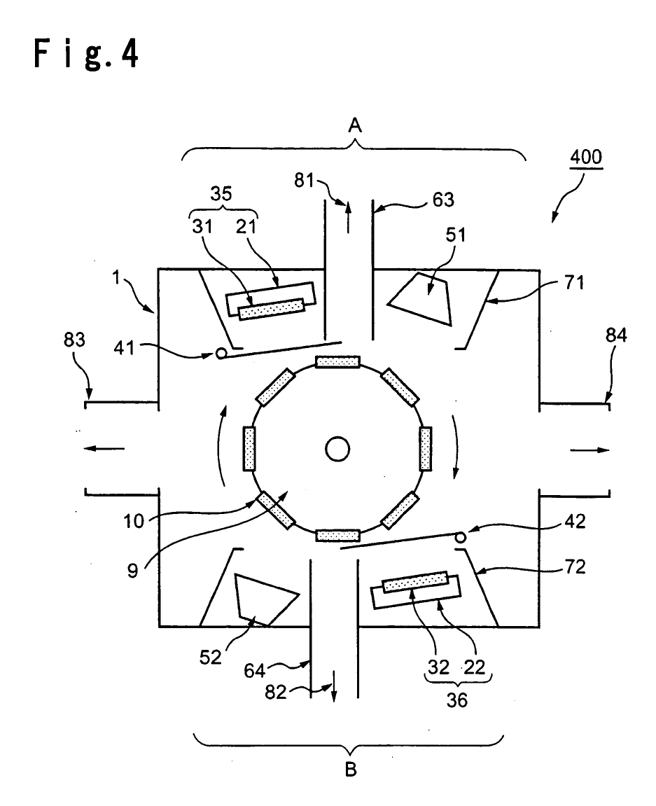

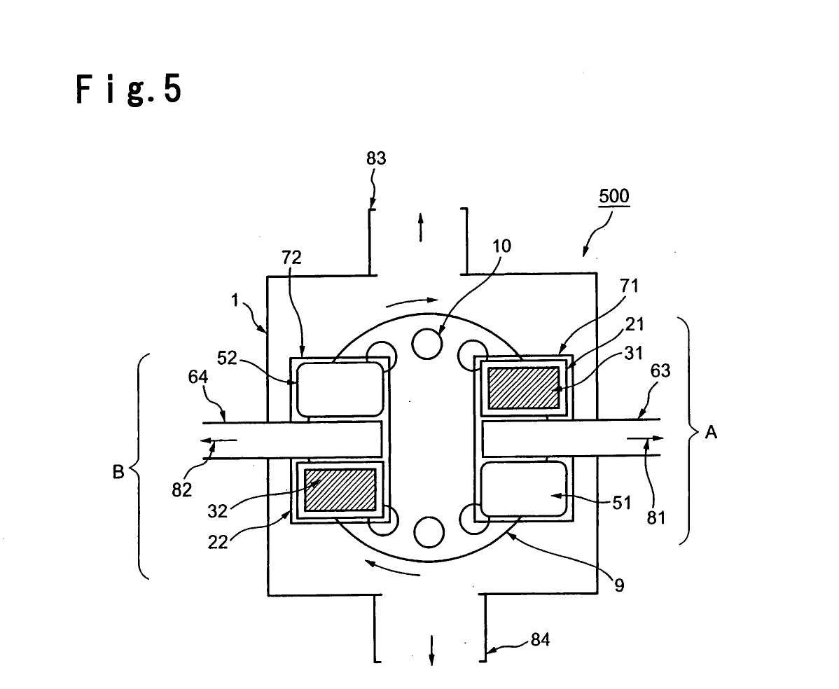

FIGS. 4 and 5 are schematic plane views showing structures of sputtering apparatuses according to embodiments of the present invention which are derived from those shown in FIGS. 1 and 2. In FIGS. 4 and 5, the partition plates 61, 62 in FIGS. 1 and 2 are replaced by partition spaces 63, 64. With such structures, the first sputtering source 35 and the first plasma generator 51 can certainly be partitioned from each other, and the second sputtering source 36 and the second plasma generator 52 can certainly be partitioned from each other.

In the following, description will be made as to the case that a dielectric film having a relatively low refractive index (hereinbelow, referred to as the L film) is deposited on a substrate by using the film deposition apparatus in FIG. 1 (FIG. 4) or FIG. 2 (FIG. 5). Here, the dielectric film means an oxide film, a nitride film, an oxynitride film, a fluoride film or the like. Specifically, the L film may be of SiO₂, SiNₓO_{y} (x<y) or the like. As the target material, it is preferred to use an electrically conductive material allowing a DC sputtering from the viewpoint of the film deposition rate, more specifically, Si, SiOₓ as an oxygen deficit type material or the like may be mentioned. Here, description will be made as to the case that as the L film, a SiO₂ film is formed as a single layer by using the sputtering apparatus 100 in FIG. 1.

In FIG. 1, a Si (B-doped conductive poly-crystal) target is set as the first target 31. Substrates 10 are mounted on the substrate holder 9 and the inside of the vacuum chamber 1 is vacuumed to be 10⁻⁴ Pa or lower. Then, the substrate holder 9 is kept at a predetermined number of revolution, e.g., 100 rpm; an Ar gas is introduced into the vacuum chamber while the first shutter 41 is closed, and a DC power is supplied to the first cathode 21, whereby pre-sputtering to the first target 31 is initiated. The number of revolution of the substrate holder 9 is preferably high as possible from the viewpoint of the film deposition rate. However, a speed of from 100 to 300 rpm is preferred in reliability of the mechanical system. Then, an oxygen gas is introduced into the first plasma generator 51, while the first shutter 41 is closed, to generate an oxygen gas plasma due to an ECR discharge as a kind of the microwave discharge. By these operations for pretreatment, conditioning (cleaning and stabilizing) to the surface of the Si target and cleaning (mainly, the removal of an organic substance) of the substrates by the reactive gas, can simultaneously be carried out.

When the discharge current and voltage to the Si target become constant and the surface of the target is stabilized, the first shutter 41 is opened while the substrate holder 9 is rotated in the direction indicated in arrow marks in FIG. 1 or FIG. 2 to initiate deposition of film on the substrates 10 by sputtering. First, the film of the Si metal as the first target material is deposited thereon by sputtering, and then, the film of the Si metal is oxidized by the oxygen gas plasma generated from the first plasma generator 51. Thus, the film deposition and oxidation are alternately conducted whereby the SiO₂ film as the L film is formed on each substrate 10. When the film thickness of the SiO₂ film reaches a predetermined value, the shutter 41 is closed to stop the film deposition.

The thickness of the Si metal layer deposited by sputtering in one time (in one revolution) should be within about one atomic layer so that the oxidation reaction by the first plasma generator 51 can be proceeded completely. For this, power supplied to the first cathode 21 and the number of revolution of the substrate holder 9 are appropriately determined. For example, in the case of the Si metal film, one atomic layer is of a thickness of about 1.5 Å, and the power to be supplied to the first cathode 21 is in a range of from 1 to 10 (W/cm ²). In this case, the density of the oxygen plasma produced in the first plasma generator 51 is preferably higher for the purpose of obtaining an oxide film having a stoichiochemically complete composition by proceeding the oxidation reaction completely. However, it should be controlled to be lower for the purpose of preventing the surface of the adjacent first target 21 from being polluted by the decomposed or excited reactive gas (oxygen) whereby a stable sputtering discharge is obtainable. Accordingly, it is preferable that the flow rate of the used oxygen gas and the microwave or high (or radio) frequency power for generating plasma are determined experimentally in consideration of the balance between the quality of the film and the film deposition rate.

As a method for preventing the surface of the adjacent target from becoming an insulator resulted from the diffusion of and pollution by the reactive gas such as excited oxygen decomposed and migrated at the plasma generator and the consequential unstable discharge, the present invention employs a method for partitioning the space between the first plasma source 35 and the first plasma generator 51 with a partition plate 61. Further, the atmosphere separating cover 71 is provided to define the first plasma generator 51 in the vacuum chamber 1 to prevent the reactive gas decomposed and migrated at the first plasma generator 51 from diffusing. In addition, the exhaust port 81 is provided in rear of the first plasma generator 51 so that the reactive gas decomposed and migrated from first plasma generator 51 can effectively be evacuated so as not to be diffused. By employing a so-called double magnetron method or twin magnetron method utilizing an AC discharge, it is possible to suppress the adverse effect by the diffusion of the reactive gas to the minimum.

As the reactive gas, oxygen, nitrogen, carbon dioxide, nitrogen dioxide, ammonia, water, hydrogen etc. are preferably used because oxidation or nitridation can effectively and accurately be conducted, and the controllability of optical characteristics of a dielectic material produced by the reaction can be excellent.

In the following, description will be made as to a method for producing a dielectric film having a relatively high refractive index (hereinbelow, referred to as the H film) by using the film deposition apparatus shown in FIG. 1 or FIG. 2. As the H film, TiO₂, Ta₂O₅, Nb₂O₃, Hf₂O₅, ZrO₂, Y₂O₃, ZnO, CeO₂, etc. can be mentioned specifically. As the target material, an electric conductive material is preferably used from the viewpoint of the film deposition rate. Specifically, Ti, Ta, Nb, Hf, Zr, Y, Zn or Ce, or TiOₓ as a oxygen deficit type material can be mentioned. By using it, a TiO₂ film can be deposited as a single layer by using the same method as for the before-mentioned SiO₂ film.

Namely, in FIG. 1, a target of a Ti metal is set as the second target 32. Substrates 10 are mounted on the substrate holder 9, and the inside of the vacuum chamber 1 is evacuated to be a low pressure of 10⁻⁴ Pa or less. The number of revolution of the substrate holder 9 is kept to a predetermined revolution, e.g., 100 rpm; an Ar gas is introduced into the vacuum chamber while the second shutter 42 is closed, and a DC power is supplied to the second cathode 22 to initiate pre-sputtering of the second target 32. Although the number of the revolution of the substrate holder 10 is preferably high as possible from the viewpoint of the film deposition rate, the number of revolution is preferably from 100 to 300 rpm in reliability of the mechanical system. Then, an oxygen gas is supplied to the second plasma generator 52 while the second shutter 42 is closed, and a microwave power is applied thereto whereby an oxygen gas plasma is generated. By such pretreatment, conditioning (cleaning and stabilizing) to the surface of the Ti target and cleaning (mainly, the removal of an organic substance) of the substrates by the reactive gas can simultaneously be carried out.

When the discharge current and voltage of the Ti target become constant, the surface of the target is stabilized, the second shutter 42 is opened while the substrate holder 9 is rotated in the direction of arrow marks in FIG. 1 or FIG. 2, to initiate the deposition of a film of the substrates 10 by sputtering. First, a film of a Ti metal as the second target material is deposited by sputtering, and then, the oxidation reaction of the Ti metal film proceeds by the oxygen gas plasma generated from the second plasma generator 52. Thus, by conducting the above-mentioned film deposition and oxidation alternately, the TiO₂ film as the H film is stacked on each substrate. When the film thickness of the TiO₂ film reaches a predetermined thickness, the second shutter 42 is closed to stop the film deposition.

Even in the case of the H film, the thickness of the Ti metal layer deposited by sputtering in one time (one revolution) should be within about one atomic layer so that the oxidation reaction at the second plasma generator 52 is proceeded completely, in the same manner in the case of the L film. For this, the power supplied to the second cathode 22 and the number of revolution of the substrate holder 9 are determined appropriately. For example, when a Ti metal is used, the thickness of one atomic layer is about 1 Å, and the power supplied to the first cathode 21 is from 0.5 to 5 (W/cm²).

Now, description will be made as to the case of depositing a SiO₂—TiO₂ mixed film as a mixed film (hereinbelow, referred to as the M film) comprising the L film and the H film by using the film deposition apparatus shown in FIG. 1 or FIG. 2.

First, Si (B-doped electrical conductive poly-crystal) metal target for the L film is set as the first target 31, and a Ti metal target for the H film is set as the second target 32. Substrates 10 are mounted on the substrate holder 9 and the inside of the vacuum chamber is evacuated to be a lower pressure of 10⁻⁴ Pa or less. Then, the number of revolution of the substrate holder 9 is kept to a predetermined revolution, e.g., 100 rpm; an Ar gas is supplied to the vacuum chamber while the first shutter 41 and the second shutter 42 are closed, and power is supplied to the first cathode 21 and the second cathode 22 to initiate sputtering. Then, an oxygen gas is supplied to the first plasma generator 51 and the second plasma generator 52 while the first shutter 41 and the second shutter 42 are closed, and a microwave power is supplied to the first and second plasma generators 51, 52 to generate oxygen gas plasma so that the substrates 10 are exposed to the plasma.

When the discharge current and voltage of both targets become constant and surfaces of the both targets are stabilized, the first shutter 41 and the second shutter 42 are simultaneously opened while the substrate holder 9 is rotated in the direction of arrow marks in FIG. 1 or FIG. 2 to initiate deposition of a film on each substrate 10 by sputtering. Here, these two shutters 41, 42 are preferably of a united type capable of opening and closing simultaneously in order to avoid a deviation in the composition ratio of the mixed film just after the initiation of the film deposition. Further, these shutters are preferably opened and closed with the same angular position with respect to the first cathode and the second cathode. Thus, when these two shutters are opened to initiate the film deposition, a film of Si metal as the the first target material is first deposited by sputtering. Then, the Si metal film is oxidized by the first plasma generator 51 to form a single SiO₂ film as the L film on each substrate 10. In this case, the density of the plasma is adjusted so that the Si metal film is completely oxidized by oxidation reaction at the first plasma generator 51. Subsequently, a film of Ti metal as the second target material is deposited by sputtering. Then, the Ti metal film is oxidized by a second plasma generator 52. In this case, the density of the plasma is adjusted so that the Ti metal is completely oxidized by oxidation reaction at the second plasma generator 52. The film deposition and oxidation of the SiO₂ film and the film deposition and oxidation of the TiO₂ film are carried out alternately according to the rotation of the substrate holder 9 whereby two kinds of oxides are mixed and a SiO₂—TiO₂ mixed film as the M film is deposited on each substrate 10. In this case, the film thickness of the TiO₂ film and the SiO₂ film as each single layer is far thinner than the wavelength of the participated light, and these thicknesses are about one atomic layer. Accordingly, as the TiO₂ film and the SiO₂ film are stacked, TiO₂ atoms and SiO₂ atoms are mixed uniformly whereby the SiO₂—TiO₂ mixed film in which two oxides are uniform in the order less than the wavelength and are composed of stoichiometrically complete compositions of each other can be formed. The refractive index of this mixed film is substantially agree with the value determined by the mixing ratio of the both oxides (composition ratio).

The mixing ratio (composition ratio) of both oxides can be controlled by changing relatively the ratio of the power supplied to the first cathode 21 to power supplied to the second cathode 22. Further, by changing the mixing ratio of the both, the M film having a designed refractive index can be deposited. For example, when the L film is a SiO₂ film (refractive index: 1.46), the H film is a TiO₂ film (refractive index: 2.36) and the M film is a SiO₂—TiO₂ mixed film, and the setting condition for the first film deposition area A is the same as the setting condition for the second film deposition area B in the vacuum chamber 1, the ratio of the power supplied to the first cathode 21 (Si) to the power supplied to the second cathode 22 (Ti) should be about 1:1 (the ratio of the power does not means the ratio of the power in absolute value but means the ratio of the power in the case that the power for forming a single film is made 1. In the following, the same as above). Then, a film having a refractive index of 1.91 can be formed. When the ratio of the power supplied to the first cathode 21 (Si) to the power supplied to the second cathode 22 (Ti) is about 3:1, a film having a refractive index of 1.69 can be formed. The above-mentioned ratio of the power can be determined experimentary in consideration of the performance and the characteristics of an apparatus used.

By stacking the H film, the L film and the M film on a substrate, a multilayer film including a mixed film having desired optical characteristics can be formed. When an M film is provided as an interlayer in a multilayer film formed by stacking alternately an H film and an L film, it is possible to suppress a ripple in a reflection or transmission spectra and reduce the number of layer in the multilayer film. Further, if an M film formed by mixing a high refractive index material and a low refractive index material can be deposited so as to indicate a predetermined refractive index as an interlayer, the target for forming the interlayer is unnecessary; an additional target-related complicated work can be reduced and cost saving is possible. In addition, by stacking the interlayer in plural layers, a multilayer film having required high optical characteristics can be produced with a smaller number of layers and productivity can remarkably be improved.

The sputtering apparatus of the present invention has two sputtering areas each provided with a plasma source and a plasma generator. The number of the sputtering areas is not limited to two, but may be three or more. The sputtering apparatus having three or more sputtering areas and the mixed film prepared by such apparatus are also included in the present invention.

Since the film produced by the method of the present invention has a stoichemically complete composition, it is easy to prepare a multilayer film having a predetermined performance according to design. As a concrete example of the multilayer film including a mixed film, there is a Rugate filter formed by stacking on a glass substrate an M₁ film, an M₂ film (Mₙ film (n: a natural number) indicates an interlayer film having a different refractive index), an H film and an L film.

The substrate used in the present invention is not in particular limited but a glass substrate, a quartz substrate or the like is preferably used. The thickness of the glass substrate is preferably from 0.5 to 2 mm in the viewpoint of strength. Further, when the sputtering apparatus of the present invention is used, and if the shape of the substrate holder is optimized for a substrate having a larger surface area or a substrate having a smaller surface area, productivity can be improved. In the case of using the substrate having a larger surface area, the shape of the substrate holder should be flat as shown in FIG. 2. A formed film may have anisotropy depending on a flying direction of a material deposited on the substrate. Such anisotropy can be avoided by forming the substrate holder to be flat. The surface area of the substrate, when the substrate is in a circular shape, is preferably from 127 to 203.2 mm in diameter.

The substrate with a multilayer film (a multilayer film device) of the present invention is useful for a device provided with a low reflective film or an edge filter (such as an infrared ray reflection filter, an ultraviolet ray reflection filter an infrared/ultraviolet ray reflection filter, a visible light reflection filter, etc.), a polarization filter etc., which are usable for a part of a display, a projector, a lighting equipment or various camera lenses. In particular, Rugate filter shows a smooth and steep frequency dependence free from a ripple and has a high degree of freedom in design. Accordingly, it is useful as an optical multilayer interference filter capable of selecting wavelengths of transmission light or reflection light.

According to the present invention, a crystalline double oxide film requiring a high temperature of around 900° C. in a usual sputtering apparatus, can be produced as a compound film at a lower temperature and with well crystallization. As an example of using two kinds of metal as such double oxide material, PbTiO₃ or BaTiO₄ may be mentioned. These have such structure that the constituent metal elements are arranged alternately. Accordingly, when the sputtering apparatus of the present invention wherein a very thin layer as thin as about one atomic layer is stacked one by one, a defectless film having excellent crystallinity can be produced at a low process temperature with good productivity.

Further, according to the present invention, as an example of using three kinds of metal as a double oxide material, YBa₂Cu₃Oₓ (X=6 to 7) can be mentioned. This material is useful for a high temperature super conducting film. This high temperature super conducting film can be formed at a low temperature by using the sputtering apparatus of the present invention, and the film having a predetermined composition ratio of elements can be prepared according to design.

Now, the present invention will be described in detail with reference to Examples. However, it should be understood that the present invention is by no means restricted to such specific Examples.

### EXAMPLE

A four-layered AR (anti-reflection) film having the below-mentioned structure is deposited by the method as described hereinafter and the obtained film is evaluated.

1) Structure of Four-Layered AR Film

Structure of four-layered AR film: Glass substrate/M₁ film/M₂ film/H film/L film

Here, the glass substrate, the M₁ film, the M₂ film, the H film and the L film are described below, and film thicknesses are in terms of optical film thicknesses.

(a) Glass substrate: BK7 (tradename: borosilicate glass), refractive index: 1.52, size: 125 mm diameter×0.525 mm thick

(b) M₁ film: A mixed film of SiO₂ and TiO₂, refractive index=1.69, film thickness=106 nm

(c) M₂ film: A mixed film of SiO₂ and TiO₂, refractive index=1.91, film thickness=95 nm

(d) H film: a TiO₂ film, refractive index=2.36, film thickness=122 nm

(e) L film: a SiO₂ film, refractive index=1.46, film thickness=94 nm

It is understood that the antireflection film having the above-mentioned structure has a reflectivity of not more than 0.5% over the entire visible light region of a wavelength of from 450 to 700 nm according to optical calculation if each film is of a stoichiometrically complete oxide.

### 2) Example 1 (Example of the Present Invention)

A four-layered AR film is deposited by using the sputtering apparatus shown in FIG. 1. First, a Si (B-doped electrically conductive poly-crystal) target is set as the first target 31, and a target of vacuum-melted Ti metal is set as the second target 32. A glass substrate 10 is mounted on the substrate holder 9, and the inside of the vacuum chamber 1 is evacuated to be a high vacuum condition of 5×10⁻⁵ Pa. Then, the substrate holder 9 is rotated at 100 rpm and 50 sccm of an Ar gas is supplied to the vacuum chamber while the first shutter 41 and the second shutter 42 are closed, to initiate pre-sputtering (the ratio of the power supplied to the Si target to the power supplied to the Ti target is 3:1). Then, 100 sccm of an oxygen gas is supplied to the first plasma generator 51 and the second plasma generator 52 respectively while the first shutter 41 and the second shutter 42 are closed, and then, a microwave power is applied to the first plasma generator 51 and the second plasma generator 52 to generate an oxygen gas plasma to be diffused onto the substrate 10. The pressure in the vacuum chamber 1 at that moment is 0.3 Pa.

When the discharge current and voltage of both targets become constant and surfaces of the both targets are stabilized, the first shutter 41 and the second shutter 42 are opened simultaneously while the substrate holder 9 is rotated in the direction of arrow marks in FIG. 1, to initiate sputtering to form a film on the glass substrate. First, a Si metal as the first target material is deposited by sputtering on the substrate. Then, the Si metal film is oxidized at the first plasma generator 51 to thereby form a SiO₂ film as the L film on the glass substrate. Subsequently, a Ti metal as the second target material is deposited by sputtering. Then, the Ti metal film is oxidized at the second plasma generator 52 whereby a TiO₂ film as the H film is stacked on the SiO₂ film. In this case, since the film thickness of each film is very thin as much as about one atomic layer, a SiO₂—TiO₂ uniformly mixed film comprising two oxides can be formed. The film deposition by sputtering is continued until the film thickness reaches 106 nm. When the thickness reaches 106 nm, the first shutter 41 and the second shutter 42 are closed simultaneously to stop the film deposition for the M₁ film.

Then, the power for the first cathode 21 and the power for the second cathode 22 are changed (the ratio of the power supplied to the Si target to the power supplied to the Ti target is 1:1), and the first shutter 41 and the second shutter 42 are simultaneously opened to initiate film deposition of the M₂ film. Since the film thickness of the M₂ film is very thin as thin as about one atomic layer in the same manner as the thickness of the M₁ film, a SiO₂—TiO₂ uniformly mixed film comprising two oxides can be formed. When the film thickness reaches 95 nm, the first shutter 41 and the second shutter 42 are closed to stop the film deposition for the M₂ film.

Then, the second shutter 42 is opened while the first shutter 41 is remained in a closing state to initiate film deposition of the H film. When the film thickness reaches 122 nm, the second shutter 42 is closed to stop the film deposition for the H film.

Finally, the first shutter 41 is opened while the second shutter 42 is remained in a closing state to initiate film deposition of the L film. When the film thickness reaches 94 nm, the first shutter 41 is closed to stop the film deposition for the L film. By the above-mentioned method, a four-layered AR film is produced.

### 3) Example 2 (Comparative Example)

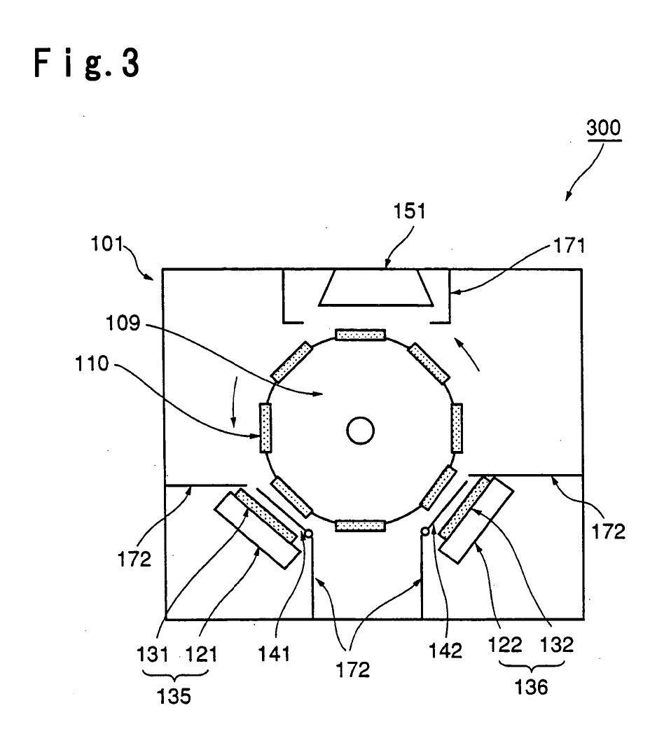

A four-layered AR film is deposited by using the sputtering apparatus shown in FIG. 3. First, a Si (B-doped electric conductive poly-crystal) target is set as the first target 131, and a target of Ti metal is set as the second target 132. A glass substrate 110 is mounted on the substrate holder 109, and the inside of the vacuum chamber 101 is evacuated to be a high vacuum condition of 10⁻⁵ Pa. Then, the substrate holder 109 is rotated at 100 rpm and pre-sputtering is initiated while the first shutter 141 and the second shutter 142 are closed (the ratio of the power supplied to the Si target to the power supplied to the Ti target is 3:1). Then, in the state that the first shutter 141 and the second shutter 142 are closed, a microwave power is applied to the plasma generator 151 to generate an oxygen gas plasma due to an ECR discharge, the plasma being diffused onto the substrate 110.

When the discharge current and voltage of both targets become constant and surfaces of the both targets are stabilized, the substrate holder 109 is rotated in the direction of arrow marks in FIG. 3 while the first shutter 141 and the second shutter 142 are opened simultaneously to initiate sputtering to form a film on the glass substrate 110. First, a Si metal as the first target material is deposited by sputtering on the substrate, and then, a Ti metal as the second target material is deposited by sputtering thereon. Subsequently, the mixed metal film composed of the Si metal and the Ti metal are oxidized by the plasma generator to form a SiO₂—TiO₂ mixed film. When the film thickness reaches 106 nm, the first shutter 141 and the second shutter 142 are closed to stop the film deposition for the M₁ film.

Then, the power for the first cathode 121 and the power for the second cathode 122 are changed (the ratio of the power supplied to the Si target to the power supplied to the Ti target is 1:1), and the first shutter 141 and the second shutter 142 are opened to initiate film deposition of the M₂ film. When the film thickness reaches 95 nm, the first shutter 141 and the second shutter 142 are closed to stop the film deposition for the M₂ film.

Then, in the state that the first shutter 141 is closed, the second shutter 142 is opened to initiate film deposition of the H film. When the film thickness reaches 122 nm, the second shutter 142 is closed to stop the film deposition for the H film.

Finally, the first shutter 141 is opened while the second shutter 142 is remained in a closing state to initiate film deposition of the L film. When the film thickness reaches 94 nm, the first shutter 141 is closed to stop the film deposition for the L film. By the above-mentioned method, a four-layered AR film is produced.

4) Evaluation of four-layered AR film The reflectivity of each glass substrate with the four-layered AR film produced in Example 1 and Example 2 is measured with a spectrophotometer (U4000 manufactured by Hitachi, Ltd.)

As a result, the reflectivity of the glass substrate with the four-layered AR film in Example 1 with respect to visible light is 0.4% which is the same as the designed value. On the other hand, the reflectivity of the glass substrate with the four-layered AR film in Example 2 with respect to visible light deviates largely from the designed value because oxidation is insufficient and the film becomes an absorptive film. Accordingly, it is confirmed that the AR film according to the designed value is not produced.

By using the sputtering apparatus of the present invention, a mixed film having an effectively zero extinction coefficient and a refractive index agreeable with a designed value can be produced without reducing the film deposition rate, and a multilayer film especially an optical multilayer film with good performance and having characteristics agreeable with a designed value can be produced by stacking such mixed film.

The entire disclosure of Japanese Patent Application No. 2003-020193 filed on Jan. 29, 2003 including specification, claims, drawings and summary is incorporated herein by reference in its entirety.

What is claimed is:

1. A sputtering apparatus comprising a vacuum chamber, a cylindrical substrate holder supported rotatably in the vacuum chamber and a substrate mounted on an outer periphery of the substrate holder wherein the vacuum chamber includes a first film deposition area and a second film deposition area for deposition of a film on the substrate, the first film deposition area includes a first sputtering source comprising a first cathode and a first target held on the first cathode and a first plasma generator located so as to be adjacent to the first sputtering source, and the second film deposition area includes a second sputtering source comprising a second cathode and a second target held on the second cathode and a second plasma generator located so as to be adjacent to the second sputtering source, and the first sputtering source and the first plasma generator are partitioned from each other and the second sputtering source and the second plasma generator are partitioned from each other.

2. The sputtering apparatus according to claim 1, wherein the first cathode and/or the second cathode comprises a pair of cathodes to which a discharge voltage is alternately applied from an AC power source or a DC pulse power source.

3. The sputtering apparatus according to claim 1, wherein a shutter means is provided so as to be opened and closed with the same angular position with respect to the first cathode and the second cathode.

4. The sputtering apparatus according to claim 1, wherein the first plasma generator and/or the second plasma generator is a plasma generator for generating plasma by a microwave discharge or an inductive or capacitive coupling type high frequency discharge.

5. A sputtering apparatus comprising a vacuum chamber, a circular disk-like substrate holder supported rotatably in the vacuum chamber and a substrate mounted on the circular disk of the substrate holder wherein the vacuum chamber includes a first film deposition area and a second film deposition area for deposition of a film on the substrate, the first film deposition area includes a first sputtering source comprising a first cathode and a first target held on the first cathode and a first plasma generator located so as to be adjacent to the first sputtering source, and the second film deposition area includes a second sputtering source comprising a second cathode and a second target held on the second cathode and a second plasma generator located so as to be adjacent to the second sputtering source, and the first sputtering source and the first plasma generator are partitioned from each other and the second sputtering source and the second plasma generator are partitioned from each other.

6. The sputtering apparatus according to claim 5, wherein the first cathode and/or the second cathode comprises a pair of cathodes to which a discharge voltage is alternately applied from an AC power source or a DC pulse power source.

7. The sputtering apparatus according to claim 5, wherein a shutter means is provided so as to be opened and closed with the same angular position with respect to the first cathode and the second cathode.

8. The sputtering apparatus according to claim 5, wherein the first plasma generator and/or the second plasma generator is a plasma generator for generating plasma by a microwave discharge or an inductive or capacitive coupling type high frequency discharge.

9. A mixed film characterized by being formed on a substrate by using the sputtering apparatus described in claim 1 and by repeating the following operations:
depositing on the substrate a film of a material for the first target, by sputtering at the first sputtering source, causing a reaction of the formed film by the first plasma generator, depositing a film of a material for the second target, by sputtering at the second sputtering source, and causing a reaction of the formed film by the second plasma generator.

10. A multilayer film including the mixed film described in claim 9.

11. A mixed film characterized by being formed on a substrate by using the sputtering apparatus described in claim 5 and by repeating the following operations:
depositing on the substrate a film of a material for the first target, by sputtering at the first sputtering source, causing a reaction of the formed film by the first plasma generator, depositing a film of a material for the second target, by sputtering at the second sputtering source, and causing a reaction of the formed film by the second plasma generator.

12. A multilayer film including the mixed film described in claim 11.
